(19) United States
(12) Patent Application Publication
(10) Pub. No.: US 2019/0343019 A1
(43) Pub. Date: Nov. 7, 2019

(54) COOLING DEVICE FOR AN ELECTRONICS MODULE

(71) Applicant: General Electric Company, Schenectady, NY (US)

(72) Inventors: Maja Harfman Todorovic, Niskayuna, NY (US); Philip Michael Cioffi, Schaghticoke, NY (US); Xu She, Cohoes, NY (US); Gary Dwayne Mandrusiak, Latham, NY (US); Rajib Datta, Niskayuna, NY (US); Michael Joseph Schutten, Rotterdam, NY (US)

(21) Appl. No.: 15/968,284

(22) Filed: May 1, 2018

(51) Int. Cl. H05K 7/20; H05K 9/00

(52) U.S. Cl. CPC H05K 7/20272; H05K 7/20927; H05K 1/0209; H05K 9/0015; H05K 9/0022

(57) ABSTRACT

A device for cooling an electronic component includes a substrate having a component mounting surface and a fluid flow surface recessed relative to the component mounting surface. The device also includes an inlet orifice positioned proximate a first end of the fluid flow surface and an outlet orifice positioned proximate a second end of the fluid flow surface. A pattern of surface features is arranged on the fluid flow surface. The pattern of surface features is configured to entrain a coolant flowing across the fluid flow surface and redirect the coolant upward and away from the fluid flow surface.

### BACKGROUND OF THE INVENTION

Embodiments of the invention relate generally to cooling devices for electronics modules and, more particularly, to fluid cooled heat sinks with enhanced heat transfer capabilities.

The electrical performance of electronic components is limited by the rate at which the heat they produce is removed. In the field of electronics, and power electronics in particular, there is a generally continuous demand for enhanced performance capabilities and increased package density all within a smaller and smaller footprint. These combined demands increase operating temperatures and thereby erode the performance capabilities of the electronic device. Heightened operating temperatures are especially prevalent in power electronics modules since they are designed to operate at increased power levels and generate increased heat flux as a result.

Thermal management of a heat generating component, such as a power electronics module, may be accomplished with a heat sink that enhances heat transfer from the heat generating component and lowers the operating temperature thereof. Conventional air-cooled heat sinks are often unable to adequately lower the operating temperature of latest generation power modules to an acceptable level. One prior art solution for enhancing heat transfer from heat generating devices such as power electronics modules is an impinging jet liquid cooled heat sink. Coolant is directed, under pressure, through small holes formed in the surface of the heat sink forming jets that impinge upon an adjacent surface of the heat generating device. The impinging jets transfer heat away from the heat source of the power electronics module, thereby maintaining the module at a lower temperature. While impinging jet technology affords high heat transfer capabilities, impinging jet systems are expensive to design and manufacture, experience a high pressure drop between the inlet and outlet of the heat sink, and are prone to surface erosion or degradation.

Accordingly, there is a need for a cooling device that addresses the above limitations and that is designed to facilitate enhanced heat transfer from heat generating components such as power electronics modules.

### BRIEF DESCRIPTION OF THE INVENTION

In accordance with one aspect of the invention, a device for cooling an electronic component includes a substrate having a component mounting surface and a fluid flow surface recessed relative to the component mounting surface. The device also includes an inlet orifice positioned proximate a first end of the fluid flow surface and an outlet orifice positioned proximate a second end of the fluid flow surface. A pattern of surface features is arranged on the fluid flow surface. The pattern of surface features is configured to entrain a coolant flowing across the fluid flow surface and redirect the coolant upward and away from the fluid flow surface.

In accordance with another aspect of the invention, a heat sink includes a substrate comprising an electrically non-conductive material, the substrate comprising a fluid flow surface recessed below a mounting surface. An inlet orifice is positioned proximate a first end of the fluid flow surface and an outlet orifice is positioned proximate a second end of the fluid flow surface. A plurality of projections extend outward from the fluid flow surface and are arranged in a pattern thereon.

In accordance with another aspect of the invention, a thermal management assembly includes a heat sink having a substrate comprising a mounting surface. The heat sink includes at least one component mounting location having a fluid inlet, a fluid outlet, and a well in fluid communication with the fluid inlet and the fluid outlet. The well comprises a fluid flow surface recessed below the mounting surface. A pattern of raised surface features project outward from the fluid flow surface. At least one heat generating component is coupled to the mounting surface.

In accordance with yet another aspect of the invention, a fluid cooled heat sink has a fluid flow surface defined thereon. The fluid flow surface includes a pattern of ridges disposed between a fluid inlet orifice and a fluid outlet orifice.

These and other advantages and features will be more readily understood from the following detailed description of preferred embodiments of the invention that is provided in connection with the accompanying drawings.

### BRIEF DESCRIPTION OF THE DRAWINGS

The drawings illustrate embodiments presently contemplated for carrying out the invention.

In the drawings:

FIG. 1 is a perspective view of a fluid cooled heat sink, according to an embodiment of the invention.

FIG. 2 is a top view of the heat sink of FIG. 1.

FIGS. 2A-2H are detail views of raised surface features that can be incorporated into the heat sink of FIG. 1, according to alternative embodiments of the invention.

FIG. 3 is a top view of a heat sink according to an alternative embodiment of the invention.

FIG. 4 is a bottom view of the heat sink of FIG. 1.

FIG. 5 is a cross-sectional view of the heat sink of FIG. 1.

FIG. 6 is a cross-sectional view of a heat sink according to an alternative embodiment of the invention.

FIG. 7 is a cross-sectional view of a thermal management system that includes the heat sink of FIG. 1, according to an embodiment of the invention.

FIG. 8 is a cross-sectional view of a thermal management system that includes the heat sink of FIG. 1, according to another embodiment of the invention.

FIG. 9 is a cross-sectional view of a fluid cooled heat sink that includes a shield configured to suppress or capture electromagnetic interference (EMI), according to an embodiment of the invention.

FIG. 10 is a cross-sectional view of a fluid cooled heat sink that includes an electromagnetic shield, according to another embodiment of the invention.

FIG. 11 is a cross-sectional view of a fluid cooled heat sink that includes an electromagnetic shield, according to yet another embodiment of the invention.

FIG. 12 is a cross-sectional view of a fluid cooled heat sink that includes an electromagnetic shield, according to yet another embodiment of the invention.

FIG. 13 is a perspective view of a multi-module fluid cooled heat sink, according to an embodiment of the invention.

FIG. 14 is a bottom view of the multi-module heat sink of FIG. 13.

FIG. 15 is a cross-sectional view of the multi-module liquid sink of FIG. 13.

FIG. 16 is a right side elevational view of the multi-module heat sink of FIG. 13.

FIG. 17 is a left side elevational view of the multi-module heat sink of FIG. 13.

FIG. 18 is a front perspective view of a multi-module fluid cooled heat sink, according to another embodiment of the invention.

FIG. 19 is a rear perspective view of the multi-module heat sink of FIG. 18.

### DETAILED DESCRIPTION

Embodiments of the present invention provide for a cooling device for one or more heat generating components. The cooling device is a fluid cooled heat sink that includes a fluid flow surface having formed thereon a pattern of raised surface features that entrain and redirect cooling medium as it travels across the fluid flow surface. In embodiments where a heat generating component is coupled directly to a mounting surface of the heat sink, the redirected portions of cooling medium impinge directly upon a heated surface of the heat generating component and enhance heat transfer therefrom. Alternatively, the redirected portions of cooling medium may be directed against the surface of an intermediate thermal interface material coupled between the heat sink and a surface of the heat generating component(s). The heat sink may be a molded or cast component, or may be formed using an additive manufacturing technique (e.g., stereolithography) that facilitates forming the heat sink as a unitary structure having a complex geometry of internal fluid passages, with the pattern of raised surface features formed during the additive manufacturing. The cooling device or heat sink may also include a shielding structure that is either formed integral to the heat sink itself or coupled between the heat sink and heat generating component and configured to mitigate electromagnetic interference. The general concept of a fluid cooled heat sink with raised surface features that enhance heat transfer can be extended to multi-module heat sinks having generally planar or three-dimensional geometries, as described in more detail below.

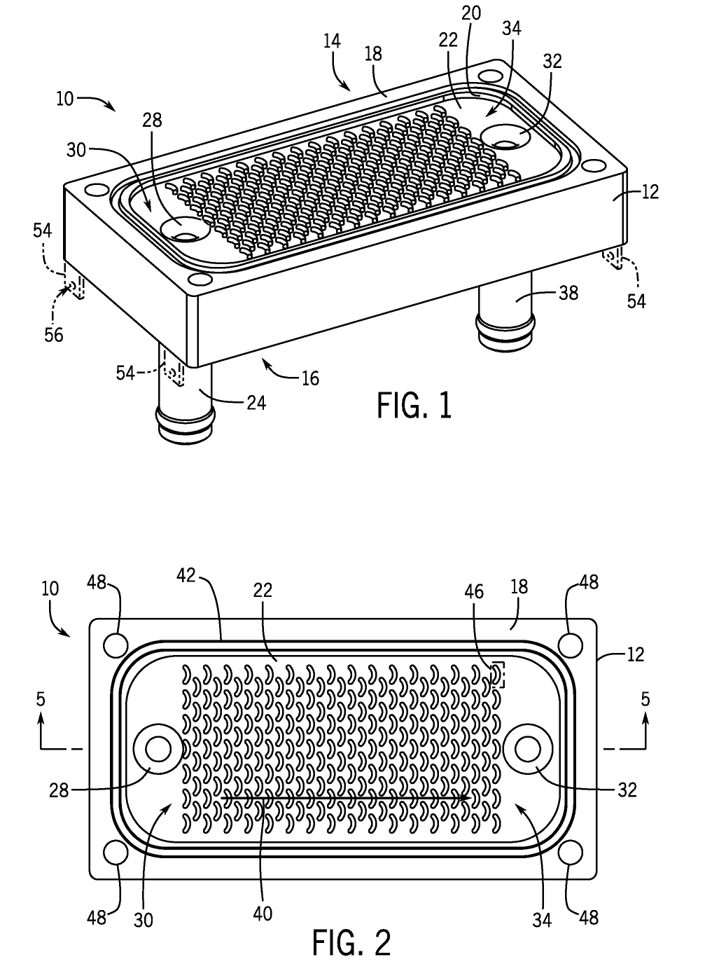

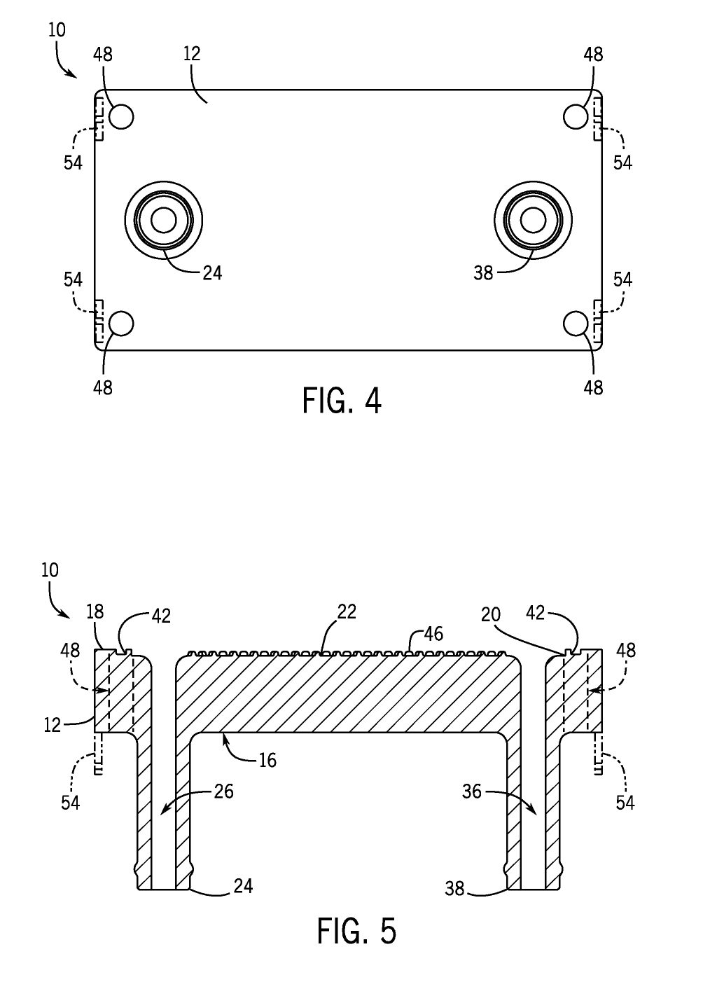

Referring now to FIG. 1, a cooling device or heat sink 10 is shown according to an embodiment of the invention. Heat sink 10 includes a substrate 12 having a top side 14 and a bottom side 16. The top side 14 includes a component mounting surface 18 and a well or recess 20 formed in a central portion of the top side 14. A fluid flow surface 22 defines the bottom surface of the well 20. A first fluid fitting 24 functions as a fluid inlet port for receiving a cooling medium. The inlet fitting 24 is coupled to a supply passage 26 (FIG. 4) that extends through a portion of the substrate 12 and terminates at an inlet orifice 28 positioned proximate a first end 30 of the well 20. An outlet orifice 32 is positioned proximate a second end 34 of the well 20. The outlet orifice 32 is coupled to an exhaust passage 36 (FIG. 4) that extends through another portion of the substrate 12. A second fluid fitting 38 is coupled to the exhaust passage 36 and functions as a fluid outlet port for the cooling medium. Thus, fluid is permitted to flow across the fluid flow surface 22 in the direction of arrow 40.

In operation, a cooling medium is directed into the inlet fitting 24 and exits from the outlet fitting 38. Inlet fitting 24 and outlet fitting 38 may include coupling devices such as valves, nozzles, and the like, to enable the heat sink 10 to be coupled to inlet and outlet fluid reservoirs (not shown). The cooling medium may be part of a closed loop or open loop system. The cooling medium may be water, an ethylene glycol solution, an alcohol, or any other material having a desirable thermal capacity to remove heat from a heat generating component coupled to the heat sink 10.

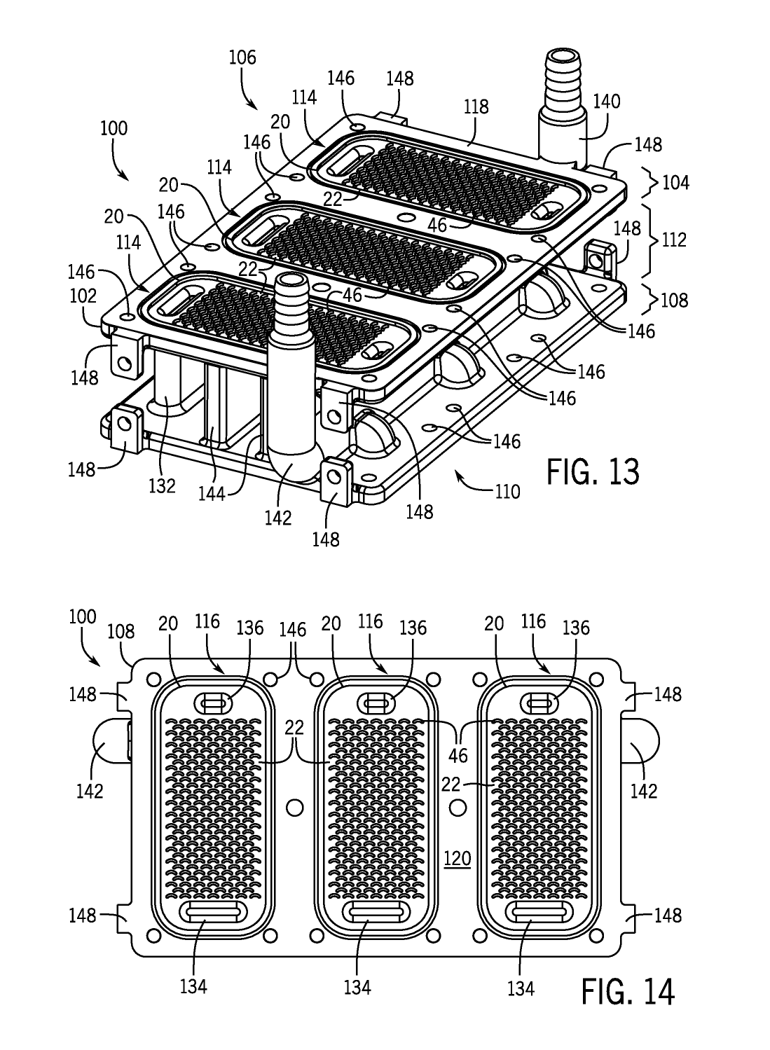

The inlet orifice 28 and outlet orifice 32 may be sized similarly, as shown in FIG. 1, or differ in size according to alternative embodiments (for example as shown in the heat sink design of FIG. 13). Inlet and outlet orifices 28, 32 also may have any cross-sectional shape, including, as non-limiting examples, a generally circular geometry as shown or a slot that extends across a portion of the width of the well 20. The size and shape of the inlet and outlet orifices 28, 32, the inlet and outlet fittings 24, 38, and the supply and exhaust passages 26, 36 are optimized to reduce the total pressure drop within the heat sink 10 and to maintain a uniform flow rate of cooling medium through inlet and outlet fittings 24, 38 and across fluid flow surface 22.

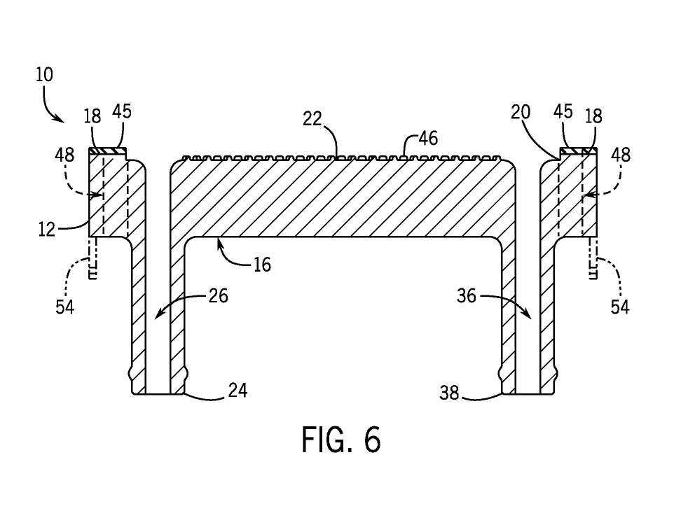

In the illustrated embodiment, the inlet fitting 24 and outlet fitting 38 are arranged generally orthogonal to the fluid flow surface 22 and extend outward from the bottom side 16 of substrate 12, as shown in FIGS. 5 and 6. The supply passage 26 defines a generally linear pathway for fluid to flow between the inlet end of the inlet fitting 24 and the inlet orifice 28. Likewise, the exhaust passage 36 defines a generally linear pathway for fluid to flow between the outlet orifice 32 and the outlet end of the outlet fitting 38. In alternative embodiments, supply and exhaust passages 26, 36 may define more complex and non-linear passageways through substrate 12 to obtain even fluid flow distribution over the fluid flow surface 22 and minimize pressure loss.

In the illustrated embodiment, the inlet and outlet orifices 28, 32 are generally aligned along the centerline of the well 20 such that the cooling medium is directed across the fluid flow surface 22 in a direction generally perpendicular to the long axis of each of the raised surface features 46. In alternative embodiments, either or both of the inlet and outlet orifices 28, 32 may be positioned off-center (e.g., proximate a corner). In such case the raised surface features 46 may reoriented to be generally orthogonal to the flow direction across fluid flow surface 22.

Although the heat sink 10 is illustrated having a generally rectangular, box-like shape, embodiments are not limited thereto. For example, bottom side 16 of the heat sink 10 may be a generally planar surface or have a curved surface topology to facilitate arranging heat sink 10 relative to other external structures. In other embodiments, the top side 14 of the heat sink 10 may have a curved surface topology that mirrors a curved mounting surface of a heat generating component.

In one embodiment, substrate 12 is an electrically non-conductive material such as a polymer, plastic, ceramic, or composite including fillers and/or additives. Substrate 12 may be thermally conductive or thermally non-conductive. In a preferred embodiment, substrate 12 is a high-temperature ceramic-plastic composite such as, for example, Accura® Bluestone™, which can handle steady-state operating temperatures (e.g., temperatures at or above 250° C.), has a rigid structure that is able to support limiting machining such as hole drilling and tapping, has sufficient strength to handle high mechanical loadings from hose clamps and nominal fluid pressures during operation. In an alternative embodiment, substrate 12 is formed from an electrically conductive material including, as non-limiting examples, copper, aluminum, or other metal or metal alloy, or a polymeric material embedded with thermally and electrically conductive fillers. One skilled in the art will recognize that substrate 12 is not limited to the listing of materials described herein and that alternative materials may be used to form substrate 12 depending on the specific application and design of the heat sink.

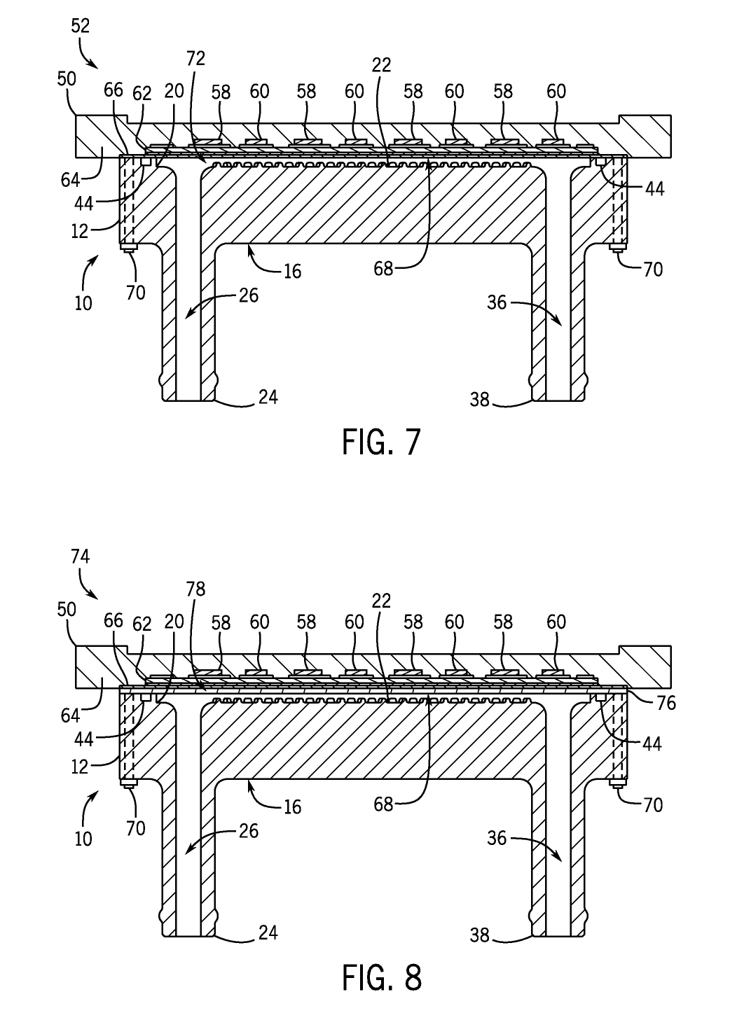

The mounting surface 18 of heat sink 10 may optionally include a recessed groove 42 that surrounds the well 20 and is sized to receive a portion of an O-ring or gasket 44 (shown in FIGS. 7 and 8). In an alternative embodiment shown in FIG. 6, the groove and gasket combination is replaced with a layer of compliant or pliable material 45 disposed on the mounting surface 18 of substrate 12 and sized to surround well 20. This layer of pliable material 45 may be formed during the 3D printing process, using an alternative deposition or printing technique, or coupled to the mounting surface 18 with an adhesive. When used, pliable material functions similar to gasket 44 to maintain a fluidically-sealed environment between the heat sink 10 and a heat generating component coupled thereto.

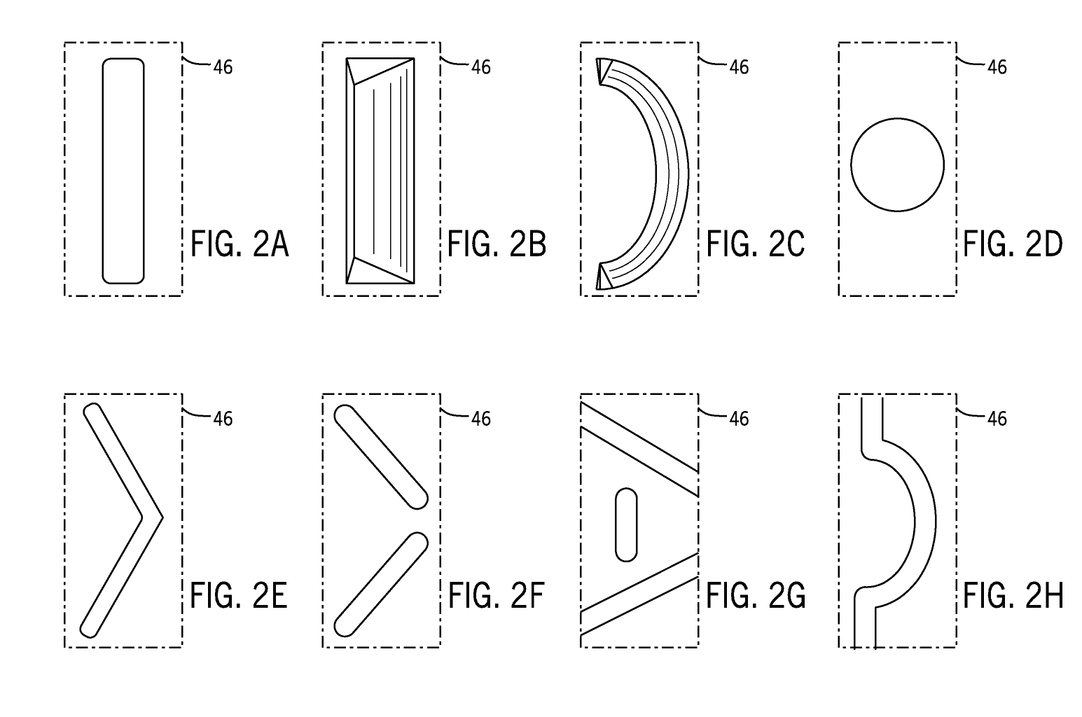

As most clearly shown in FIG. 2, the fluid flow surface 22 includes a pattern of surface features 46 located between the fluid inlet 28 and fluid outlet 32. The surface features 46 are raised projections or ridges that extend outward from the fluid flow surface 22 and are configured to disrupt and redirect the flow of the cooling medium as it passes across the fluid flow surface 22. The raised surface features 46 entrain portions of the cooling medium and redirect that cooling medium upward and away from the fluid flow surface 22 in a generally perpendicular direction relative to the arrow 40. These entrained portions of cooling medium form pseudo jets that provide a heat transfer capability comparable to impinging jets with the benefits of reduced cost, reduced surface feature erosion risk, and lower pressure drop. In alternative embodiments, surface features 46 may be formed over more or less of the fluid flow surface 22 than illustrated in FIG. 2.

In the illustrated embodiment, raised surface features 46 are discrete curved, arcuate, or crescent-shaped ridges that are arranged in alternating or offset rows across the fluid flow surface 22. In such an arrangement, cooling medium that passes through a gap formed between two adjacent surface features 46 in one row impinges upon a surface feature 46 in the next row. The illustrated pattern of surface features 46 includes alternating rows of six (6) or seven (7) surface features 46. Alternative embodiments may have more or less surface features per row. The raised surface features 46 function as ramps to direct coolant upward toward the surface of an adjacent heated component. Additionally, the height and spacing of the raised surface features 46 serve to accelerate and decelerate the flow of cooling medium across the fluid flow surface 22 to further augment the convective coefficient of heat transfer from the adjacent heated surface. The raised surface features 46 thus function to form an array of flow velocity distributed jets (referred hereafter as “pseudo jets”) within the cooling medium flow. These pseudo jets enhance heat transfer between the fluid and an adjacent heated surface, resulting in high local convective coefficients within the immediate zone of impact between the heated surface and a respective pseudo jet.

In one exemplary and non-limiting embodiment, the raised surface features 46 are ridges that have a height of approximately 1.0 mm, a width or thickness of approximately 1.0 mm, and a length of approximately 4 mm. In such an embodiment, the well 20 may have a width of approximately 45 mm and a length of approximately 105 mm, with the depth of the well 20 spaced approximately 1.5 mm away from the top surface of the raised surface features 46. The dimensions of the well 20 and the dimensions of the raised surface features 46 may be modified in alternative embodiments to enhance heat transfer based on the design specifications of a particular application.

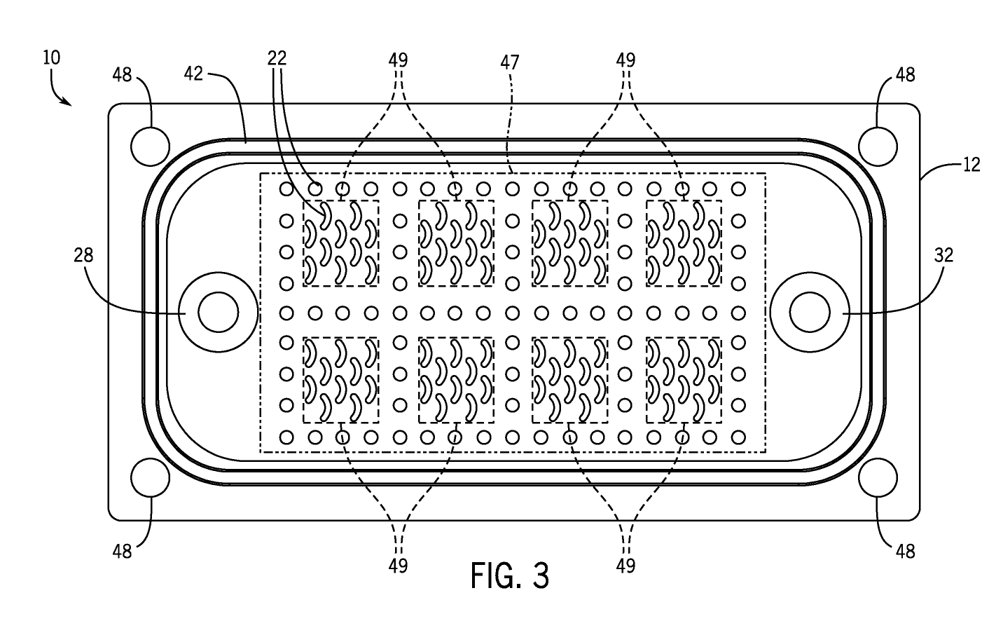

In the embodiment illustrated in FIG. 2, the raised surface features 46 have a uniform pattern on fluid flow surface 22. Alternatively, the raised surface features 46 may have a non-uniform or random pattern across the fluid flow surface 22 or form a pattern that is solely concentrated in one or more locations fluid flow surface 22 to concentrate flow and enhance heat transfer from one or more local hot spots on the adjacent heated surface of the heat generating component. In yet another embodiment, the raised surface features 46 may form different patterns in different regions on the fluid flow surface 22. FIG. 3 is a top view of heat sink 10 according to an alternative embodiment where fluid flow surface 22 is divided into a number of different regions 47, 49. Region 47 include an array of raised surface features arranged in one pattern and regions 49 include an array of raised surface features in a different pattern. The differing patterns may include different shapes of raised surface features and/or raised surface features arranged with different spacing. For example, a different type of surface feature and/or different inter-feature spacing may be used in regions 49 that will be located under each semiconductor die incorporated within a heat generating component.

While illustrated herein as crescent-shaped ridges, it is contemplated that the raised surface features 46 may have numerous other geometries that similarly function to form pseudo jets within the flow of cooling medium. For example, raised surface features 46 may have other curved or arcuate geometries, may be a series of dashed straight-line segments, or may have an open waffle pattern formed from a series of bisecting dashed lines. FIGS. 2A-2H illustrate a number of alternative geometries for raised surface features 46. The raised surface features 46 may be formed as a linear projection (FIG. 2A) or as a linear ramp (FIG. 2B). Raised surface features 46 may also be curved, arcuate, or crescent-shaped ramps similar to that shown in FIG. 2C. Raised surface features 46 may also include a pattern of bumps or dots (FIG. 2D) on the fluid flow surface 22. Alternatively, the raised surface features 46 may be closed v-shaped projections (FIG. 2E), open v-shaped projections (FIG. 2F), a series of angled and straight-line segments (FIG. 2G), or a combination of straight and curved line segments (FIG. 2H). In some embodiments, each row of raised surface features 46 within the overall pattern includes multiple, discrete projections similar to that shown in FIG. 2. In alternative embodiments each row of the pattern is formed from a single projection that spans the width of the pattern. The geometric configuration utilized for raised surface features 46 and the overall shape and size of recess 20 may depend on parameters such as flow resistance, the type of cooling medium, and the desired maximum operating temperature of the heat generating component, as non-limiting examples. Thus, raised surface features 46 may have alternative geometries or arrangements than that specifically illustrated or described herein.

In a preferred embodiment, substrate 12 and its associated raised surface features 46 are manufactured as a unitary structure manufactured using an additive manufacturing process such as three-dimensional printing or stereolithography (SLA). Inlet and outlet fittings 24, 38 may also be manufactured as part of the unitary structure using the additive manufacturing process. Substrate 12 may also be manufactured as a unitary structure (with or without inlet and outlet fittings 24, 38) by a known casting, molding, or machining process. In yet other embodiments, substrate 12 may be formed as a multi-layer structure with inlet and outlet fittings 24, 38 provided as separate components bonded or coupled together by an adhesive, fasteners, or other known joining means. The well 20 and its raised surface features 46 may be formed by a variety of alternative manufacturing processes including, but not limited to, as part of a casting, molding, machining, or additive manufacturing process, using a stamping technique, using a known material removal process (e.g., milling, grinding, drilling, boring, etching, eroding, etc.), or using an additive process (e.g., printing, deposition, etc.).

Heat sink 10 may include one or more surface mounting features 48 that facilitate mounting heat sink 10 to a heat generating component 50 to form a thermal management assembly 52 such as that shown in FIG. 7. In the illustrated embodiment, mounting features 48 are through-holes that extend through a thickness of the substrate 12. Mounting features 48 may be mounting flanges or other structural components in alternative embodiments.

In some embodiments, heat sink 10 may also include one or more additional mounting features 54 (shown in phantom in FIG. 1) to facilitate mounting heat sink 10 to an external assembly (not shown) or for mounting other components (also not shown) to the heat sink 10 itself. Mounting features 54 are illustrated in FIG. 1 as flanges that project outward from substrate 12. One or more fastener openings 56 may be formed within each flange. It is understood that the geometry of mounting features 54 may vary based on a particular application such that the particular size, shape, number, and positioning of mounting features 54 may be selected based on that particular application.

Referring now to FIG. 7, in one non-limiting embodiment heat generating component 50 is a power electronics module or package configured for a high-power application, such as an electric motor drive circuit of an electric vehicle or hybrid-electric vehicle. Power electronics module 50 includes an arrangement of semiconductor die 58 and other electronic components 60 coupled to a direct bonded copper substrate 62 and positioned within a housing 64. A copper baseplate 66 defines the bottom surface 68 of the heat generating component 50. Fasteners 70 (such as bolts, for example) extend through the mounting features 48 to couple heat sink 10 to the heat generating component 50. One skilled in the art will recognize that power electronics module 50 may include a number of other components including a bus bar, passive components, and electrical interconnections, which have been omitted from the figures for purposes of clarity.

While heat generating component 50 is described herein as a power electronics package, it is understood that heat sink 10 can be configured to facilitate thermal management of any number of alternative types of heat generating components and/or alternative types of electronics packages or components than that described above. Thus, embodiments of the invention are not limited only to the specifically illustrated devices and arrangements thereof. As used herein the term “electrical component” may be understood to encompass various types of semiconductor devices, including without limitation, IGBTs, MOSFETs, power MOSFETs, and diodes, as well as resistors, capacitors, inductors, filters and similar passive devices and/or combinations thereof. In such instances, the position, geometry, spacing, and/or number of surface mounting features 48 may be modified to facilitate mounting the heat sink 10 to the heat generating component 50.

In the embodiment illustrated in FIG. 7, the bottom surface 68 of the heat generating component 50 and the mounting surface 18 of the heat sink 10 are assembled in direct contact with one another, such that a cavity 72 is formed between the copper baseplate 66 of the heat generating component 50 and the well 20. In an alternative embodiment illustrated in FIG. 8, a thermal management assembly 74 includes one or more thermal interface material (TIM) layers 76 interposed between the heat generating component 50 and heat sink 10. In such case, a cavity 78 is formed between a bottom surface of TIM layer(s) 76 and the well 20. The TIM layer(s) 76 may include, without limitation, adhesives, thermal greases, thermal pastes, films, compliant thermal pads, or the like. In one exemplary embodiment, TIM layer(s) 76 is a mixture of a polymer and a conductive filler material such as an epoxy resin mixed with Al₂O₃ or AlN.

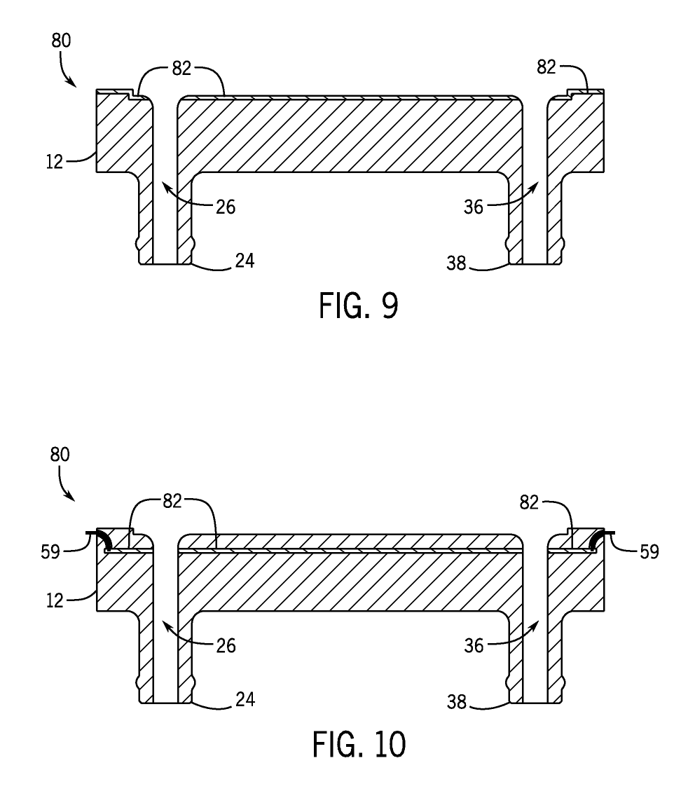

FIG. 9 is a cross-sectional view of a heat sink 80 according to an alternative embodiment of the invention that includes a shield 82 configured to capture or suppress electromagnetic interference (EMI). Heat sink 80 includes a number of similar components as heat sink 10 (FIG. 1), which are referred to with common part numbering as appropriate. In the illustrated embodiment, shield 82 is a conformal structure disposed over the top side 14 of the substrate 12. Shield 82 conforms to or adapts to the shape of the surface topology of substrate 12, thereby coating the mounting surface 18, the sidewalls of the well 20, the fluid flow surface 22, and the raised surface features, which are omitted from the cross-sectional view for purposes of clarity. In some embodiments, shield 82 may also extend at least partially into inlet plenum 24 and outlet plenum 38. Shield 82 may maintain substantially the same thickness over the entirety of the outward-facing surface of substrate 12, or have some areas thinner than others (e.g., on the sidewalls of the well 20).

In an alternative embodiment illustrated in FIG. 10, shield 82 is embedded within substrate 12 such that the shield 82 is entirely or substantially surrounded by the electrically non-conducting material of substrate 12. Shield 82 is a continuous structure with openings formed at the locations of inlet and outlet ports 24, 38. The shield 82 of FIG. 10 is constructed to enable an electrical connection be made to the shield 82 in order to properly reference the shield 82 for EMI purposes. When the shield 82 is entirely embedded within the substrate 12, this electrical connection is made to shield 82 by way of one or more wired connections 59 that extend through a portion of substrate 12. Alternatively, wired connection(s) 59 may be replaced by a screw or other type of connector or a portion of the shield 82 may extend entirely outside the substrate 12 or come to an external surface of the substrate 12 thereby facilitating an electrical connection to be made to the shield 82. In some embodiments, shield 82 and/or the underlying substrate 12 are constructed in a manner that provides a mounting location for a removable or hardwired electrical connection (not shown) to the shield 82. In other embodiments, an electrical connection to the 82 may be made by feeding a wire (not shown) through a passageway formed in substrate 12. It is to be understood that heat sink 80 of FIG. 10 includes raised surface features similar to those described above, which have been omitted from the cross-sectional view for purposes of clarity.

The shield 82 of FIGS. 9 and 10 is constructed from any appropriate material for at least partially attenuating or absorbing the energy of, reflecting, or cancelling electromagnetic radiation or waves. In some embodiments, shield 82 is constructed from an electrically conductive material such as copper, silver, nickel, aluminum, or aluminum nitride as non-limiting examples. Shield 82 may be formed by applying a conductive paint, using a metal deposition technique such as, for example, a sputtering and/or electroplating technique, other electroless method, or as part of an additive manufacturing technique such as stereolithography. Alternatively, shield 82 may be provided as a sheet of material that is embedded within the substrate 12 during the additive manufacturing process as non-limiting examples. Shield 82 may be a single conductive layer or a stack of conductive layers. In some embodiments, shield 82 includes a barrier layer or plating layer (e.g., titanium, nickel, or an alloy thereof) that is disposed on substrate 12 and a thicker layer of electrically conductive material such as copper, aluminum, or any other appropriate material, disposed on the barrier or plating layer. Shield 82 may also include layers of different types of materials selected to shield or capture different frequency components of electromagnetic radiation, for example a first layer that shields low frequency components and a second layer that shields high frequency components. When heat sink 80 is coupled to a heat generating component such as the power module 50 of FIG. 7, shield 82 functions to shield or capture EMI noise generated by the heat generating component 50.

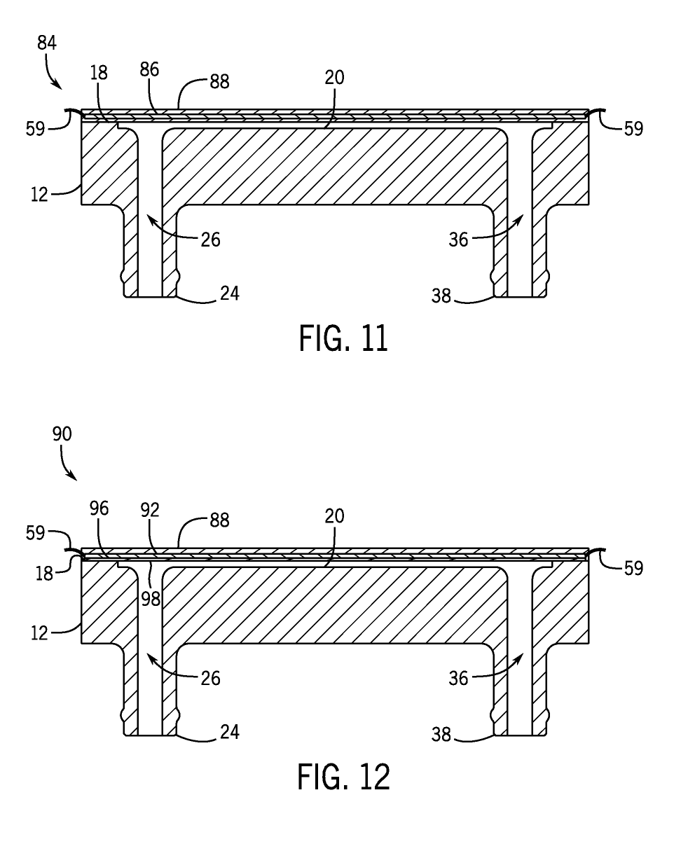

FIG. 11 is a cross-sectional view of a heat sink 84 that includes an electromagnetic shield 86 according to an alternative embodiment of the invention. Heat sink 84 includes a number of components similar to those in FIG. 8, which are referred to with common part numbering as appropriate. The shield 86 in FIG. 11 is embedded within one or more TIM layers 88 coupled to the mounting surface 18 of substrate 12. Similar to shield 82 of FIG. 9, shield 86 may be a single conductive layer or multiple conductive layers formed from any of the same materials described with respect to shielding structure 82. Shield 86 may be deposited onto an intermediate layer of TIM layer structure 88 using any of the deposition, printing, or plating techniques described above or may be provided as a prefabricated sheet that is embedded within TIM layer 88.

In yet another embodiment, shown in FIG. 12, a heat sink 90 includes a shield 92 that is suspended directly over the well 20. In such an embodiment, shield 92 is provided as a conductive sheet of material that is bonded to the substrate 12 of heat sink 10, such as via solder, pressure contact, or other known coupling means. Shield 92 may include any of the same electrically conductive materials described with respect to shield 82 (FIG. 9). As the lower surface of the shield 92 is in direct contact with the cooling medium, shield 92 may be formed as a multi-layer structure composed of a thicker core conductive layer 96 and a plating layer 98 (e.g., nickel) positioned facing well 20 to mitigate corrosion. It is to be understood that the fluid flow surface within the well 20 of the FIGS. 11 and 12 embodiments includes raised surface features similar to raised surface features 46 described above, which have been omitted from the drawings for purposes of clarity.

By integrating an electromagnetic shielding structure 82, 86, 92 on or within a heat sink, the embodiments described with respect to FIGS. 9, 10, 11, and 12 provide cooling and shielding functionality within a common structure.

Referring now to FIG. 13, a multi-module heat sink 100 is illustrated according to an embodiment of the invention. Multi-module heat sink 100 is a double-sided heat sink structure formed from a unitary substrate 102. In a preferred embodiment, the unitary substrate 102 is formed from an electrically non-conducting polymer or composite material, such as those described with respect to substrate 12 (FIG. 1) and is formed using an additive manufacturing technique such as 3D printing or stereolithography. In alternative embodiments, and depending on the overall geometry of the substrate 102 and fluid flow passages formed therein, substrate 102 may alternatively be formed using a known molding or casting techniques and from either an electrically non-conducting polymer or a conductive material.

The unitary substrate 102 can be generally described as including three main portions: a first mounting plate portion 104 on the first side 106 of the multi-module heat sink 100, a second mounting plate portion 108 on the second side 110 of the multi-module heat sink 100, and a coolant passage portion 112 positioned between the first and second portions 104, 108. The first mounting plate portion 104 includes three (3) generally co-planar mounting locations 114. Similarly, the second mounting plate portion 108 includes three (3) generally co-planar mounting locations 116. Thus, multi-module heat sink 100 provides discrete mounting locations for six (6) heat generating components in the configuration shown. It is contemplated that heat sink 100 may be modified to provide mounting locations for more or less heat generating components in alternative embodiments.

As best shown in FIGS. 13 and 14, each mounting location 114, 116 includes a well 20, similar to that described with respect to heat sink 10 (FIG. 1), which is recessed relative to the respective mounting surface 118, 120 of the first and second mounting plate portions 104, 108. The fluid flow surface 22 within the well 20 includes a pattern of raised surface features 46 that are illustrated having a similar crescent shaped geometry as described with respect to heat sink 10. However, the size, shape, and overall pattern of raised surface features 46 may be otherwise configured based on any of the alternative configurations described above. Optionally, heat sink 80 may include any of the shielding structures described with respect to FIGS. 9-12 formed over the outward-facing surfaces of the first and second sides 106, 110.

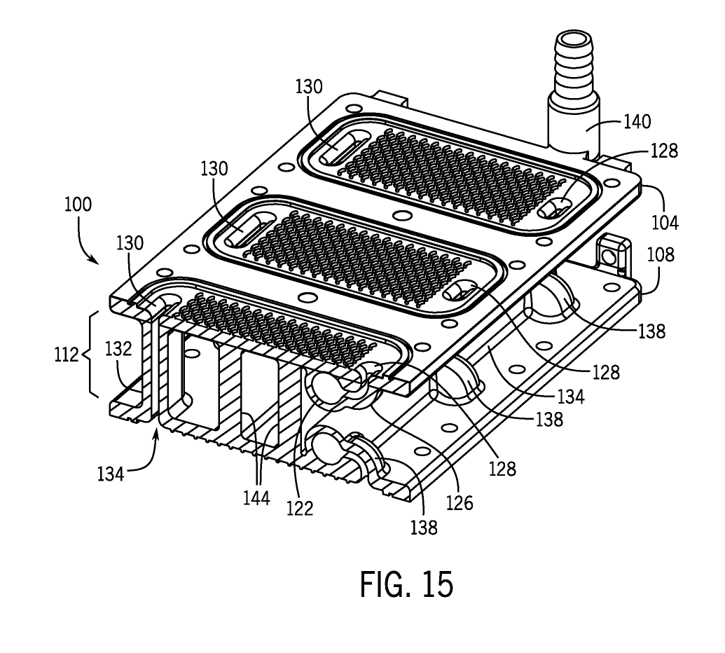

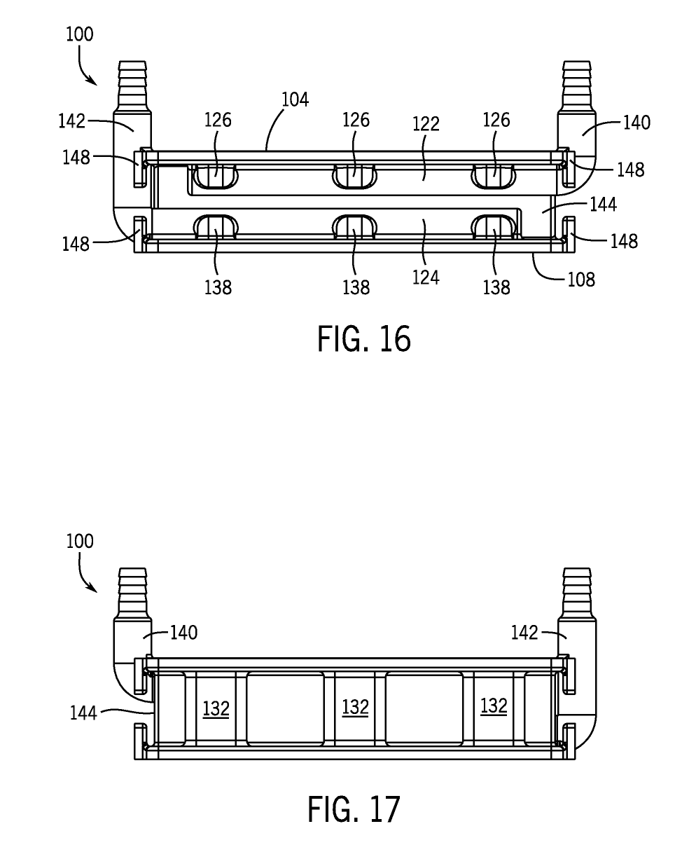

Referring now to FIGS. 15 and 16, the coolant passage portion 112 of multi-module heat sink 100 includes a fluid inlet manifold 122 and a fluid outlet manifold 124 that are formed within substrate 102. A series of inlet branch passages 126 extend off of the fluid inlet manifold 122 and fluidically couple the fluid inlet manifold 122 to the inlet orifices 128 on the first mounting plate portion 104. In operation, cooling medium is directed across the fluid flow surfaces 22, is entrained and redirected through contact with textured surface pattern 74, and is directed into outlet orifices 130. Each outlet orifice 130 is coupled to a respective fluid passage 132 that extends through the coolant passage portion 112 of substrate 102 and fluidically couples one of the outlet orifices 130 on the first mounting plate portion 104 to a respective inlet orifice 134 located on the second mounting plate portion 108 opposite the respective outlet orifice 130. Cooling medium is then directed across the fluid flow surfaces 22 located on second mounting plate portion 108 and into respective outlet orifices 136, shown most clearly in FIG. 17. A series of outlet branch passages 138 fluidically couple the outlet orifices 136 to fluid outlet manifold 124.

Cooling medium is directed into the fluid inlet manifold 122 through an inlet fluid fitting 140 and exits multi-module heat sink 100 through an outlet fluid fitting 142 coupled to fluid outlet manifold 124. Inlet and outlet fittings 140, 142 may be located on opposing ends of the multi-module heat sink 100 as shown, on the same end, or in any alternative configuration that facilitates connections to external fluid reservoirs (not shown).

Inlet and outlet orifices 128, 130, 134, 136, inlet branch passages 126, outlet branch passages 138, and fluid inlet and outlet manifolds 122, 124 are sized relative to one another to optimize flow uniformity throughout the coolant passage portion 112. In one embodiment, the inlet orifices 128 on first mounting plate portion 104 are sized larger than the outlet orifices 130 on first mounting plate portion 104, as shown in FIG. 13. The opposite is true on second mounting plate portion 108, with the outlet orifices 136 being formed larger than the inlet orifices 134, as shown in FIG. 14. In one exemplary and non-limiting embodiment, the aforementioned components of coolant passage portion 112 are sized to define an approximate 10:1 ratio in manifold flow area to total branch flow area. However, the relative manifold to branch sizing may have other ratios based on the overall number of mounting locations, the particular parallel and/or series coupling of the mounting locations, the size and geometry of the wells, the overall size and geometry of the substrate 102, the type of cooling medium used, as well as other factors. Thus, it is to be understood that the geometry of the coolant passage portion 112 is not limited to the particular implementations illustrated and described herein and could have any number of alternative geometries designed to optimize pressure drop and maintain a reasonably balanced or uniform flow rate of cooling medium through heat sink 100.

As disclosed herein, multi-module heat sink 100 is configured to supply cooling medium in parallel to three pairs of mounting locations 114, 116, with each of those three pairs of mounting locations 114, 116 coupled together in series. However, the coolant passage portion 112 may be designed to define alternative fluid paths and to couple all or select groupings of mounting locations 114, 116 in alternative series and/or parallel arrangements. As one example, all of the mounting locations 114, 116 may be connected in series, with the inlet fitting 140 coupled to the inlet orifice 128 of one of the mounting locations 114 and the outlet fitting 142 coupled to one of the outlet orifices 136. In yet another non-limiting example, all of the inlet orifices 128, 134 may be coupled to a common manifold thereby defining a parallel flow path across all mounting locations 114, 116. In yet other alternative configurations, the coolant passage portion 112 may be designed to provide one or more individual mounting locations 104 with a dedicated fluid inlet passage or include multiple inlet passages, with each passage configured to optimize the fluid flow rate and/or pressure drop for a particular type of heat generating component.

Coolant passage portion 112 also includes one or more support structures 144 that extend between first mounting plate portion 104 and second mounting plate portion 108 and provide structural support for multi-module heat sink 100. In the illustrated embodiment, heat sink 100 includes two structural supports 144 that each span the approximate width of the heat sink 100. It is contemplated that the size, shape, number, and position of structural supports may vary from that shown in alternative multi-module heat sink configurations depending on a number of factors, including the overall heat sink size and geometry, material properties of substrate 102, application, environmental conditions, and the like. In yet other embodiments, support structures 144 may be omitted entirely, with the structural support being provided instead by fluid passageways that extend between the first and second mounting plate portions 104, 108.

Each mounting location 114 includes one or more surface mounting features 146 sized and positioned to facilitate mounting a heat generating component to the multi-module heat sink 100 above the respective mounting location 114. In the embodiment shown, the mounting features 146 are through holes formed through a thickness of the respective mounting plate portion 104, 108. However, it is to be understood that the position, size, shape, and overall geometry of mounting features 146 may be modified to facilitate the mounting of different types of heat generating components. For example, mounting features 146 may be formed as flanges or other types of structures that extend outward from the respective mounting plate portion 104, 108.

Multi-module heat sink 100 may also include one or more additional mounting features 148 (shown in phantom) to facilitate mounting multi-module heat sink 100 to one or more external components. Similar to mounting features 146, external mounting features 148 may be extended structures, such as flanges, or simple through holes formed through a portion of the substrate 102.

While multi-module heat sink 100 is illustrated and described as a unitary two-sided structure, the general concept of a multi-module heat sink described herein may be extend to single-sided multi-module heat sink configurations or multi-module heat sinks formed from two or more individual structures bonded together using known bonding materials and/or techniques. For example, a two-sided multi-module heat sink may be formed from two or more sub-sections that are separately manufactured and assembled together to form a structure similar to that of multi-module heat sink 100.

In the illustrated embodiment, the mounting locations 114 are configured to cool similar types of heat generating components (e.g., power module 50 of FIG. 7). Thus, the respective mounting locations 114 and wells 20 are commonly sized and include a similar pattern of raised surface features 46 and mounting features. In alternative embodiments, the multi-module heat sink 100 different mounting locations configured to optimize cooling of a variety of different types of components. In such case, each mounting location may have a different arrangement of mounting features, a different pattern or type of raised surface features, and/or differ in the size and/or shape of its respective well.

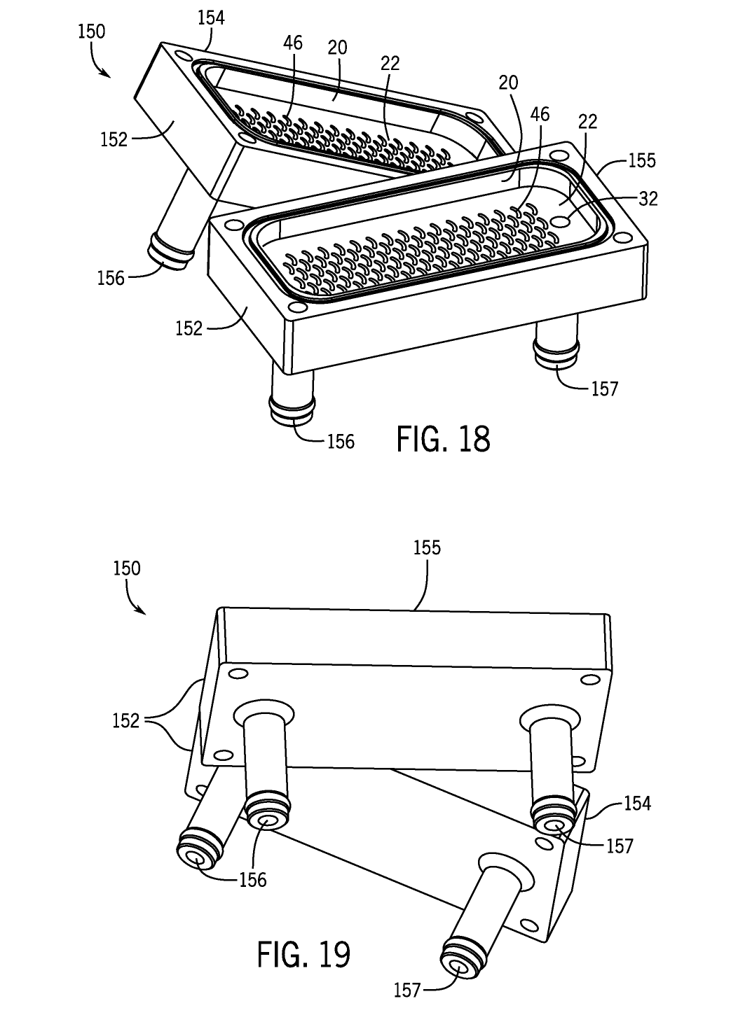

The multi-module heat sink concept may further be extended to heat sink configurations having non-planar fluid flow surfaces. FIGS. 18 and 19, for example, illustrate a non-planar multi-module heat sink 150. Similar to multi-module heat sink 100 (FIG. 13), the core structure of non-planar multi-module heat sink 150 is a unitary substrate 152 that may be formed from any of the electrically non-conductive polymeric or ceramic materials described above. Preferably, substrate 152 is a 3D printed component or is formed using an alternative additive manufacturing process that facilitates manufacture of the complex three-dimensional geometry thereof. In alternative embodiments, heat sink 150 may be assembled from multiple discrete components coupled or bonded to one another to form the desired three-dimensional geometry.

Substrate 152 includes a number of discrete mounting locations 154, 155 formed on outward-facing surfaces of the non-planar multi-module heat sink 150. As shown, the fluid flow surface 22 of mounting location 154 is non-coplanar with the fluid flow surface 22 of mounting location 155. While illustrated as including two discrete mounting locations 154, 155, alternative embodiments of heat sink 150 may include three or more mounting locations with non-coplanar fluid flow surfaces. Mounting locations 154, 155 may be configured in a similar manner as the mounting locations 114 described above, each having a well 20 including a fluid flow surface 22 with any of the raised surface feature configurations described with respect to FIGS. 1-3. The raised surface features may have a similar pattern and geometry at all mounting locations 154, 155 or may vary from location to location to optimize heat transfer for different types of heat generating components.

In the illustrated embodiment, heat sink 150 includes a dedicated fluid inlet passage 156 for each mounting location 154, 155. Fluid inlet passages 156 supply cooling medium in parallel to the inlet orifices (not shown) at each mounting location 154, 155. Cooling medium is directed across the pattern of raised surface features 46 formed on the fluid flow surface 22 at each mounting location 154, 155 and into a respective outlet orifice 32. A fluid outlet passage 157 is fluidically coupled to each outlet orifice 32.

In an alternative embodiment, multi-module heat sink 150 may include a single fluid inlet and a single fluid outlet and an internal fluid passage formed within substrate 152 to fluidically couple the outlet orifice 32 of one of the mounting locations 154, 155 to the inlet orifice 28 of the other mounting location 155, 154. In yet other alternative embodiments, multi-module heat sink 150 may be designed having inlet and outlet manifolds (to couple select subsets of mounting locations 154, 155 in parallel flow arrangements), include dedicated inlet and outlet supplies for some or all of the mounting locations 154, 155 or be configured to define serial flow paths through some or all of the mounting locations 154, 155 of heat sink 150. Similar to that described relative to multi-module heat sink 100, the relative sizing of inlet and outlet orifices, inlet and outlet passages, and inlet and outlet manifold is selected to optimize fluid flow and maintain a desired pressure drop through non-planar multi-module heat sink 150.

Optionally, multi-module heat sink 150 may include any of the shielding structures described with respect to FIGS. 9-12 provided at all or select mounting locations 154, 155.

Beneficially, embodiments of the invention disclosed herein provide heat sink designs that enhance heat transfer from an adjacent heat generating component. The heat sink designs and configurations disclosed herein include raised surface features that interact with and redirect cooling medium as it flows between the inlet and outlet orifices of the heat sink. Pseudo jets, which are formed as a result of the interaction, impinge upon the heated surface of an adjacent heat generating component and enhance heat transfer therefrom.

The heat sink designs disclosed herein present a number of benefits over prior art heat sink designs, and impinging jet heat sinks in particular. While the peak local heat transfer coefficients produced by the raised surface features may be comparatively lower than those produced by known impinging jet technologies, the combined effect of the entire array of pseudo jets results in an average convective heat transfer coefficient on an adjacent heated surface that is significantly higher than that produced by the discrete impinging jets of the prior art. A heat sink with a pattern of raised surface features also operates at a lower pressure drop than typically impinging jet heat sink designs. Furthermore, heat sinks having fluid flow surfaces with raised surface features may be operated at channel flow velocities far below the threshold values normally associated with surface erosion, thereby improving part life and reducing maintenance costs. As just one example, the fluid flow velocity over raised surface features 46 may be in the approximate range of 1-3 m/s as compared to a 6-8 m/s fluid flow velocity through a given jet of a typical impinging jet heat sink.

Therefore, according to one embodiment of the invention, a device for cooling an electronic component includes a substrate having a component mounting surface and a fluid flow surface recessed relative to the component mounting surface. The device also includes an inlet orifice positioned proximate a first end of the fluid flow surface and an outlet orifice positioned proximate a second end of the fluid flow surface. A pattern of surface features is arranged on the fluid flow surface. The pattern of surface features is configured to entrain a coolant flowing across the fluid flow surface and redirect the coolant upward and away from the fluid flow surface.

According to another embodiment of the invention, a heat sink includes a substrate comprising an electrically non-conductive material, the substrate comprising a fluid flow surface recessed below a mounting surface. An inlet orifice is positioned proximate a first end of the fluid flow surface and an outlet orifice is positioned proximate a second end of the fluid flow surface. A plurality of projections extend outward from the fluid flow surface and are arranged in a pattern thereon.

According to yet another embodiment of the invention, a thermal management assembly includes a heat sink having a substrate comprising a mounting surface. The heat sink includes at least one component mounting location having a fluid inlet, a fluid outlet, and a well in fluid communication with the fluid inlet and the fluid outlet. The well comprises a fluid flow surface recessed below the mounting surface. A pattern of raised surface features project outward from the fluid flow surface. At least one heat generating component is coupled to the mounting surface.

According to yet another embodiment of the invention, a fluid cooled heat sink has a fluid flow surface defined thereon. The fluid flow surface includes a pattern of ridges disposed between a fluid inlet orifice and a fluid outlet orifice.

While the invention has been described in detail in connection with only a limited number of embodiments, it should be readily understood that the invention is not limited to such disclosed embodiments. Rather, the invention can be modified to incorporate any number of variations, alterations, substitutions or equivalent arrangements not heretofore described, but which are commensurate with the spirit and scope of the invention. Additionally, while various embodiments of the invention have been described, it is to be understood that aspects of the invention may include only some of the described embodiments. Accordingly, the invention is not to be seen as limited by the foregoing description, but is only limited by the scope of the appended claims.

What is claimed is:

1. A device for cooling an electronic component, the device comprising:
a substrate having a component mounting surface and a fluid flow surface recessed relative to the component mounting surface;
an inlet orifice positioned proximate a first end of the fluid flow surface;
an outlet orifice positioned proximate a second end of the fluid flow surface; and
a pattern of surface features arranged on the fluid flow surface, the pattern of surface features configured to entrain a coolant flowing across the fluid flow surface and redirect the coolant upward and away from the fluid flow surface.

2. The cooling device of claim 1 wherein the pattern of surface features is formed between the inlet orifice and the outlet orifice.

3. The cooling device of claim 1 wherein the pattern of surface features comprises a plurality of ridges.

4. The cooling device of claim 3 wherein the ridges are crescent-shaped.

5. The cooling device of claim 1 further comprising:
a first fitting fluidically coupled to the inlet orifice through a first passage in the substrate; and
a second fitting fluidically coupled to the outlet orifice through a second passage in the substrate.

6. The cooling device of claim 1 wherein the substrate comprises an electrically insulating material.

7. The cooling device of claim 1 wherein the substrate comprises an electrically conductive material.

8. The cooling device of claim 1 wherein the substrate comprises a thermally conductive material.

9. The cooling device of claim 1 wherein the substrate comprises a thermally non-conductive material.

10. The cooling device of claim 1 wherein the component mounting surface comprises a groove sized to receive a portion of a gasket.

11. The cooling device of claim 1 wherein the component mounting surface comprises a layer of pliable material.

12. The cooling device of claim 1 further comprising an electromagnetic shield.

13. The cooling device of claim 12 wherein the electromagnetic shield comprises a conformal structure disposed over the component mounting surface and the fluid flow surface.

14. A heat sink comprising:
a substrate comprising an electrically non-conductive material, the substrate comprising a fluid flow surface recessed below a mounting surface;
an inlet orifice positioned proximate a first end of the fluid flow surface;
an outlet orifice positioned proximate a second end of the fluid flow surface; and
a plurality of projections extending outward from the fluid flow surface and arranged in a pattern thereon.

15. The heat sink of claim 14 wherein the plurality of projections comprises a pattern of curved ridges that entrain and redirect a flow of coolant between the inlet orifice and the outlet orifice.

16. The heat sink of claim 14 wherein the plurality of projections are arranged in a series of offset rows.

17. The heat sink of claim 14 wherein the substrate comprises a three-dimensionally printed structure.

18. The heat sink of claim 14 further comprising an electrically conductive shielding structure disposed on or within the substrate.

19. The heat sink of claim 14 wherein the plurality of projections are arranged in a first pattern within a first region of the fluid flow surface and in a second pattern within a second region of the fluid flow surface.

20. A thermal management assembly comprising:
a heat sink comprising:
a substrate comprising a mounting surface; and
at least one component mounting location comprising:
a fluid inlet;
a fluid outlet;
a well in fluid communication with the fluid inlet and the fluid outlet, the well comprising a fluid flow surface recessed below the mounting surface; and
a pattern of raised surface features projecting outward from the fluid flow surface; and
at least one heat generating component coupled to the mounting surface.

21. The thermal management assembly of claim 20 wherein the pattern of raised surface features is configured to entrain and redirect cooling medium onto the at least one heat generating component.

22. The thermal management assembly of claim 20 wherein the pattern of raised surface features comprises a plurality of curved structures.

23. The thermal management assembly of claim 20 wherein the at least one component mounting location comprises a first component mounting location and a second component mounting location; and
wherein the at least one heat generating component comprises a first heat generating component coupled to the first component mounting location and a second heat generating component coupled to the second component mounting location.

24. The thermal management assembly of claim 23 wherein a fluid flow surface of the first component mounting location is non-coplanar with a fluid flow surface of the second component mounting location.

25. The thermal management assembly of claim 20 wherein a cavity is formed between a bottom surface of the at least one heat generating component and the well.

26. The heat sink of claim 20 wherein the substrate comprises a non-electrically conductive polymer.

27. The heat sink of claim 20 wherein the substrate comprises a unitary three-dimensionally printed structure.

28. A fluid cooled heat sink having a fluid flow surface defined thereon, the fluid flow surface comprising a pattern of ridges disposed between a fluid inlet orifice and a fluid outlet orifice.

29. The fluid cooled heat sink of claim 28 wherein the ridges are one of crescent-shaped, arcuate, and v-shaped.

30. The fluid cooled heat sink of claim 28 wherein the fluid flow surface defines a bottom surface of a well.

31. The fluid cooled heat sink of claim 28 wherein the pattern of ridges is configured to entrain and redirect a coolant upward and away from the fluid flow surface.
